(19) United States
(12) Patent Application Publication
(10) Pub. No.: US 2010/0155802 A1
(43) Pub. Date: Jun. 24, 2010

(54) Semiconductor device and method of forming semiconductor device

(75) Inventor: Masahiko Ohuchi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/654,465

(22) Filed: Dec. 22, 2009

(30) Foreign Application Priority Data
Dec. 24, 2008 (JP) P2008-326908

(51) Int. Cl. H01L 27/108; H01L 21/02

(52) U.S. Cl. 257/306; 438/381; 257/E21.008; 257/E27.086

(57) ABSTRACT

A method of forming a semiconductor device includes the following processes. First grooves are formed in a first insulating layer. A conductive material is formed which fills in each of the first grooves. A first mask is formed over the first insulating layer and the conductive material. The first mask has openings that define second grooves crossing the first grooves in plan view. The second grooves are formed in the first insulating layer and the conductive material by using the first mask. A plurality of conductive pillars are formed by removing a part of the conductive material in each of the first grooves.

### BACKGROUND OF THE INVENTION

1. Field of the Invention

The present invention relates to a semiconductor device and a method of forming the semiconductor device. More specifically, the present invention relates to a semiconductor device including a pillar electrode and a method of forming the semiconductor device.

Priority is claimed on Japanese Patent Application No. 2008-326908, filed Dec. 24, 2008, the content of which is incorporated herein by reference.

2. Description of the Related Art

In recent years, shrinkage of semiconductor devices such as DRAMs (Dynamic Random Access Memories) reduces the area for memory cells included therein. Three dimensional-shaped memory cell capacitors may generally have large capacity, even if the area for memory cell including the capacitor is reduced. For example, the memory cell capacitor has a pillar-shaped bottom electrode (columnar bottom electrode). The side surface of the pillar-shaped bottom electrode provides a large contact area with a dielectric film of the capacitor. The dielectric film may perform as a capacitive insulating film of the capacitor. The large contact area will ensure a large capacity for the capacitor.

Appropriate selection of a material for the pillar electrode of the capacitor is important for ensuring sufficiently large electrostatic capacitance without reducing the leakage breakdown voltage of the capacitor. Ru (ruthenium) can generally be used for the pillar electrode of the capacitor. The next generation design rule after the 45 nm-design rule is been considered, and Ru can also be considered as a pillar-electrode material.

The pillar-electrode is formed by etching a pillar-electrode material layer. An oxygen-containing etching gas such as an oxygen-based etching gas can generally be used to etch the Ru-layer to form the Ru-pillar-electrode. In general, it has been known that a photoresist film or a carbon film can be used as a mask to pattern a metal layer. Neither the photoresist film nor the carbon film can be used as a mask when the oxygen-containing etching gas is used, because the photoresist film and the carbon film have no or insufficient etching resistance to the oxygen-containing etching gas.

Japanese Unexamined Patent Application, First Publication No. 2001-217407 discloses that, for the above-reasons, an opening is formed in an insulating layer insulator, and Ru is filled in the opening so as to form a pillar electrode for a capacitor.

In order to form the shrunken pillar electrode, an opening having an extremely high aspect ratio needs to be formed in an insulating layer. Advanced semiconductor manufacturing equipment has the upper limit of aspect ratio of the opening, for example, an aspect ratio of about 22. Advanced semiconductor manufacturing equipment is difficult to form an opening with higher aspect ratio than about 22.

The layout of DRAM memory cells is being shifted from 8F2 type to 6F2 type and then the layout will probably be shifted to 4F2 in future. Thus, the memory cell size has been on rapid decrease more and more. For these reasons, the opening with such a high aspect ratio needs to form the pillar electrode as long as the above-described method is used.

There has been a different method to form an opening for capacitor than the method using a pattern having a hole as a mask, wherein the hole is formed by a single exposure process.

Japanese Unexamined Patent Application Publication No. 2003-229497 discloses that a hard mask pattern having an opening is formed in an inter-layer insulator by two exposure processes. A hard mask material such as polysilicon is filled in the groove. Then, a selected portion of the inter-layer insulator is removed by an etching process so as to form a capacitor hole in the selected portion of the inter-layer insulator, wherein the selected portion of the inter-layer insulator is not covered by the hard mask material.

Japanese Unexamined Patent Application Publication No. 2005-150333 discloses a lower film is provided over a film which is subjected to the etching process. An upper layer is formed over the lower layer. The lower film is processed to form a first mask pattern over the film. The first mask pattern has first linear openings which extend in a first direction. The upper film is processed to form a second mask pattern over the first mask pattern. The second mask pattern has second linear openings which extend in a second direction. The second direction is perpendicular to the first direction. The second linear openings cross the first linear openings to form crossing points between the first and second linear openings. The crossing points form penetrating openings which reach the surface of the film which is subjected to the etching process. Namely, the combined mask including the first and second mask patterns performs as a mask patter which has dot-openings which are formed by the crossing points between the first and second linear openings. The combined mask is used to carry out an etching process which etches the layer under the combined mask.

The above-techniques relate to the formation of the mask pattern to form holes in the inter-layer insulator. The above-techniques are difficult to form holes having high aspect ratio. Thus, the above-techniques are difficult to form pillar electrodes by filling Ru in the capacitor openings which have high aspect ratio. The above-techniques are still difficult to form a dynamic random access memory which includes the pillar electrodes.

### SUMMARY

In one embodiment, a method of forming a semiconductor device may include, but is not limited to, the following processes. First grooves are in a first insulating layer. Conductive films are formed which fill in the first grooves. A first mask is formed over the first insulating layer and the conductive films. The first mask has openings that cross the conductive films in the first grooves in plan view. Second grooves are formed in the first insulating layer and the conductive films by using the first mask. The second grooves cross the first grooves. The second grooves define the conductive films into conductive pillars.

In another embodiment, a method of forming a semiconductor device may include, but is not limited to, the following processes. First grooves are formed in a first insulating layer. Conductive films are formed which fill in the first grooves. A first mask is formed over the first insulating layer and the conductive films. The first mask has openings that cross the conductive films in the first grooves in plan view. The conductive films in the first grooves are selectively removed by using the first mask, to define the conductive films into conductive pillars.

In still another embodiment, a semiconductor device may include, but is not limited to, an insulating layer; contact plugs in the insulating layer; pillar electrodes extending upwardly from the contact plugs; and an insulating supporter which connects the pillar electrodes to each other. The insulating supporter supports the pillar electrodes. The insulating supporter has a width which is substantially identical with a first dimension of the pillar electrodes. The first dimension is defined in a horizontal direction perpendicular to an extending direction of the insulating supporter.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary plan view illustrating a semiconductor device in accordance with a first embodiment of the present invention;

FIG. 1B is a fragmentary cross sectional elevation view illustrating the semiconductor device, taken along an A-A′ line of FIG. 1A;

FIG. 1C is a fragmentary cross sectional elevation view illustrating the semiconductor device, taken along a D-D′ line of FIG. 1A;

FIG. 2A is a fragmentary plan view illustrating a semiconductor device in a step involved in a method of forming the semiconductor device in accordance with the first embodiment of the present invention;

FIG. 2B is a fragmentary cross sectional elevation view taken along a A-A′ line of FIG. 2A;

FIG. 2C is a fragmentary cross sectional elevation view taken along a B-B′ line of FIG. 2A;

FIG. 3A is a fragmentary plan view illustrating a semiconductor device in a step subsequent to the step of FIGS. 2A, 2B, and 2C involved in the method of forming the semiconductor device in accordance with the first embodiment of the present invention;

FIG. 3B is a fragmentary cross sectional elevation view taken along a A-A′ line of FIG. 3A;

FIG. 3C is a fragmentary cross sectional elevation view taken along a B-B′ line of FIG. 3A;

FIG. 4A is a fragmentary plan view illustrating a semiconductor device in a step subsequent to the step of FIGS. 3A, 3B, and 3C involved in the method of forming the semiconductor device in accordance with the first embodiment of the present invention;

FIG. 4B is a fragmentary cross sectional elevation view taken along a A-A′ line of FIG. 4A;

FIG. 4C is a fragmentary cross sectional elevation view taken along a B-B′ line of FIG. 4A;

FIG. 5A is a fragmentary plan view illustrating a semiconductor device in a step subsequent to the step of FIGS. 4A, 4B, and 4C involved in the method of forming the semiconductor device in accordance with the first embodiment of the present invention;

FIG. 5B is a fragmentary cross sectional elevation view taken along a A-A′ line of FIG. 5A;

FIG. 5C is a fragmentary cross sectional elevation view taken along a B-B′ line of FIG. 5A;

FIG. 6A is a fragmentary plan view illustrating a semiconductor device in a step subsequent to the step of FIGS. 5A, 5B, and 5C involved in the method of forming the semiconductor device in accordance with the first embodiment of the present invention;

FIG. 6B is a fragmentary cross sectional elevation view taken along a A-A′ line of FIG. 6A;

FIG. 6C is a fragmentary cross sectional elevation view taken along a B-B′ line of FIG. 6A;

FIG. 7A is a fragmentary plan view illustrating a semiconductor device in a step subsequent to the step of FIGS. 6A, 6B, and 6C involved in the method of forming the semiconductor device in accordance with the first embodiment of the present invention;

FIG. 7B is a fragmentary cross sectional elevation view taken along a A-A′ line of FIG. 7A;

FIG. 7C is a fragmentary cross sectional elevation view taken along a B-B′ line of FIG. 7A;

FIG. 8A is a fragmentary plan view illustrating a semiconductor device in a step subsequent to the step of FIGS. 7A, 7B, and 7C involved in the method of forming the semiconductor device in accordance with the first embodiment of the present invention;

FIG. 8B is a fragmentary cross sectional elevation view taken along a A-A′ line of FIG. 8A;

FIG. 8C is a fragmentary cross sectional elevation view taken along a B-B′ line of FIG. 8A;

FIG. 9A is a fragmentary plan view illustrating a semiconductor device in a step subsequent to the step of FIGS. 8A, 8B, and 8C involved in the method of forming the semiconductor device in accordance with the first embodiment of the present invention;

FIG. 9B is a fragmentary cross sectional elevation view taken along a A-A′ line of FIG. 9A;

FIG. 9C is a fragmentary cross sectional elevation view taken along a B-B′ line of FIG. 9A;

FIG. 9D is a fragmentary cross sectional elevation view taken along a C-C′ line of FIG. 9A;

FIG. 10A is a fragmentary plan view illustrating a semiconductor device in a step subsequent to the step of FIGS. 9A, 9B, 9C and 9D involved in the method of forming the semiconductor device in accordance with the first embodiment of the present invention;

FIG. 10B is a fragmentary cross sectional elevation view taken along a A-A′ line of FIG. 10A;

FIG. 10C is a fragmentary cross sectional elevation view taken along a D-D′ line of FIG. 10A;

FIG. 11 is a fragmentary cross sectional view illustrating a DRAM memory cell having pillar electrodes in accordance with the second embodiment of the present invention;

FIG. 12 is a fragmentary cross sectional elevation view illustrating a semiconductor device in a step involved in a method of forming the semiconductor device of FIG. 11 in accordance with the second embodiment of the present invention; and

FIG. 13 is a fragmentary cross sectional elevation view illustrating a semiconductor device in a step subsequent to the step of FIG. 12 involved in the method of forming the semiconductor device of FIG. 11 in accordance with the second embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a method of forming a semiconductor device may include, but is not limited to, the following processes. First grooves are formed in a first insulating layer. A conductive material is formed which fills in each of the first grooves. A first mask is formed over the first insulating layer and the conductive material. The first mask has openings that define second grooves crossing the first grooves in plan view. The second grooves are formed in the first insulating layer and the conductive material by using the first mask. A plurality of conductive pillars are formed by removing a part of the conductive material in each of the first grooves.

In some cases, the second grooves may be formed by selectively removing the first insulating layer and having the conductive material remain in the first grooves; and removing the part of the conductive material which remains in the first grooves. In this cases, the part of the conductive material may be removed by an anisotropic etching process using an oxygen-containing gas. The first mask may include, but is not limited to, a stack of first and second layers in this order. The first layer is not etched by the oxygen-containing gas and the second layer is etched by the oxygen-containing gas.

The conductive material includes Ru, and the first mask includes a carbon layer.

The method of forming the semiconductor device may include, but is not limited to, the following additional processes. An interlayer insulator is formed under the first insulating layer. Contact plugs are formed in the interlayer insulator before forming the first insulating layer. The first grooves expose upper surfaces of the contact plugs. The conductive material connects directly to the contact plugs. The first grooves may be formed in the first insulating layer by the following processes. A second mask is formed over the first insulating layer. The second mask has a line-and-space pattern. Spaces of the line-and-space pattern of the second mask extend over the contact plugs in plan view. The first insulating layer may be selectively etched by using the second mask to form the first grooves in the first insulating layer. The second mask may be formed over the first insulating layer by the following processes. A second insulating layer may be formed over the first insulating layer. A first resist pattern may be formed on the second insulating layer. The first resist pattern has a first line-and-space pattern. Spaces of the first line-and-space pattern extend over the contact plugs in plan view. The spaces and lines of the first line-and-space pattern extend in parallel to an extension direction along which the first grooves extend. The second insulating layer may be selectively etched by using the first resist pattern to define the second insulating layer into the second mask. The first mask may be formed by the following processes. A third insulating layer may be formed over the conductive material and the first insulating layer. A second resist pattern may be formed on the third insulating layer. The second resist pattern has a second line-and-space pattern. Lines of the second line-and-space pattern extend over the contact plugs in plan view. Spaces of the second line-and-space pattern cross the conductive material that fills in the first grooves. The third insulating layer may be selectively etched to define the second insulating layer into the first mask. The first mask may include a first anti-reflection film that includes silicon oxynitride. The second mask includes a second anti-reflection film that includes silicon oxynitride. The first anti-reflection film performs as an anti-reflector when a first exposure process is carried out to form the first resist pattern. The second anti-reflection film performs as an anti-reflector when a second exposure process is carried out to form the second resist pattern. The second lines and spaces of the line-and-space pattern extend in a direction perpendicular to an extending direction along which the first grooves extend.

The method may further include, but is not limited to, removing the first insulating layer under the first mask after forming the second grooves. The method may furthermore include, but is not limited to, forming a fourth insulating layer in the first insulating layer. The fourth insulating layer connects the conductive pillars to each other, and the fourth insulating layer supports the conductive pillars during removing the first insulating layer. The method may furthermore include, but is not limited to, forming a dielectric film on the conductive pillars; and forming a top electrode on the dielectric film, to operate as capacitors.

In another embodiment, a method of forming a semiconductor device may include, but is not limited to, the following processes. A first insulating layer is formed. First openings are formed in the first insulating layer to penetrate the first insulating layer. Each of the openings extends in a first direction in plan view. A conductive film is filled into the first openings. A first mask is formed on the first insulating layer and the conductive film. The first mask has second openings. Each of the second openings extends in a second direction which crosses to the first direction in plan view. A dry etching is performed to remove a part of the conductive film which is exposed from the first mask for forming a plurality of conductive pillars made of the conductive film. The dry etching is performed by using at least a first gas and a second gas, the second gas being different from the first gas.

The first mask may include, but is not limited to, a first mask layer and a second mask layer on the first a ask layer. The first mask layer is not etched by the first gas. The first gas includes oxygen. The method may include, but is not limited to, removing the conductive film on the first insulating layer and remaining the conductive film in the first openings before forming the first mask.

In still another embodiment, a semiconductor device may include, but is not limited to, an insulating layer, contact plugs in the insulating layer, pillar electrodes extending upwardly from the contact plugs; and an insulating supporter. The supporter connects the pillar electrodes to each other. The insulating supporter supports the pillar electrodes. The insulating supporter has a width which is substantially identical with a first dimension of the pillar electrodes. The first dimension is defined in a horizontal direction perpendicular to an extending direction of the insulating supporter. The semiconductor device may include, but is not limited to, transistors eclectically connected to the pillar electrodes; dielectric insulating film covering the pillar electrodes; and a top electrode disposed facing to each of the pillar electrodes with an intervention of a dielectric insulating film therebetween.

### First Embodiment

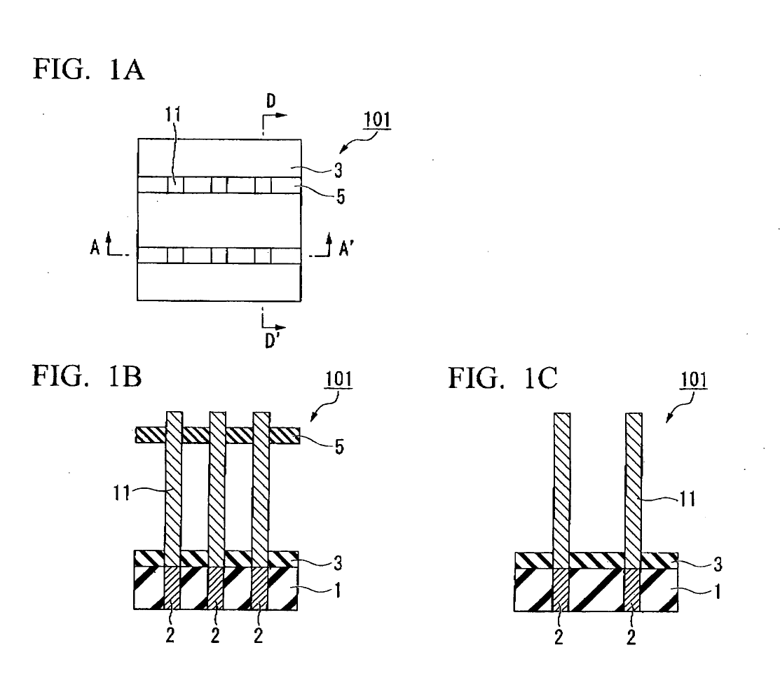

FIG. 1A is a fragmentary plan view illustrating a semiconductor device in accordance with a first embodiment of the present invention. FIG. 1B is a fragmentary cross sectional elevation view illustrating the semiconductor device, taken along an A-A′ line of FIG. 1A. FIG. 1C is a fragmentary cross sectional elevation view illustrating the semiconductor device, taken along a D-D′ line of FIG. 1A.

With reference to FIG. 1A, a semiconductor device 101 may include, but is not limited to, a first insulating film 3, third insulating films (silicon nitride film) 5 over the silicon nitride film 3, and pillar electrodes 11 extending upwardly from the silicon nitride film 5. The third insulating films 5 each have a linear shape or a stripe shape in plan view. The third insulating films 5 extend in a first horizontal direction which is parallel to the A-A′ line of FIG. 1A and perpendicular to the D-D′ line of FIG. 1A. The first insulating film 3 may include, but is not limited to, a silicon nitride film. The pillar electrodes may be made of Ru.

As shown in FIG. 1B, the semiconductor device 101 may include, but is not limited to, an insulating interlayer 1 having contact holes in which contact plugs 2 buried therein. The semiconductor device 101 also includes the silicon nitride film 3 over the insulating interlayer 1. The semiconductor device 101 also includes the pillar electrodes 11 which penetrate the silicon nitride film 3. The pillar electrodes 11 are connected to the contact plugs 2. The semiconductor device 101 also includes the silicon nitride films 5 which mechanically support the pillar electrodes 11. The silicon nitride film 5 is provided to mechanically connect, but electrically isolate, the pillar electrodes 11. The pillar electrodes 11 extend upwardly. The silicon nitride film 5 performs as a supporter which mechanically connects the pillar electrodes 11 with each other and which supports the pillar electrodes 11. The silicon nitride film 5 can prevent the pillar electrodes 11 from falling down. As shown in FIG. 1B, the silicon nitride film 5 extend horizontally at a higher level than the silicon nitride film 3. The silicon nitride film 5 is distanced in a vertical direction from the silicon nitride film 3. The silicon nitride film 5 mechanically connects upper portions of the pillar electrodes 11 with each other.

As shown in FIG. 1C, the semiconductor device 101 may include, but is not limited to, the insulating interlayer 1 having contact holes in which the contact plugs 2 are buried therein. The semiconductor device 101 also includes the silicon nitride film 3 over the insulating interlayer 1. The pillar electrodes 11 penetrate the silicon nitride film 3. The pillar electrodes 11 are connected to the contact plugs 2.

The aspect ratio of the pillar electrodes 11 is defined by a ratio of the vertical dimension, for example, the height, of the pillar electrodes 11 to a smaller one of horizontal dimensions of the bottom portion of the pillar electrodes 11. As shown in FIG. 1A, the pillar electrodes 11 may be rectangular shaped. In this case, the aspect ratio of the pillar electrodes 11 is defined by a ratio of the vertical dimension, the height, to the shorter side dimension of the bottom portion of the pillar electrodes 11. The aspect ratio of the pillar electrodes 11 may be, but is not limited to, 22 or higher.

Ru can be available for the pillar electrodes 11. A layer of Ru can be etched by using an oxygen-containing gas such as an oxygen-based gas. The material for the pillar electrodes 11 may be any other metals than Ru as far as the other metals can be etched by an oxygen-containing gas.

At the upper parts of the pillar electrodes 11, the third insulating film (silicon nitride film) 5 is formed to extend while connecting the intermediate parts of the pillar electrodes 11 in vertical direction which can also be called to as a height direction. For this reason, even though the pillar electrodes 11 are formed to have a small diameter, the silicon nitride film 5 supports the upper parts of the pillar electrodes 11, such that collapse of the pillar electrodes 11 can be reduced.

At the base ends of the pillar electrodes 11, the first insulating film (silicon nitride film) 3 is formed. For this reason, even though the pillar electrodes 11 are formed to have a small diameter, the silicon nitride film 3 supports the base ends of the pillar electrodes 11, such that collapse of pillar electrodes 11 can be reduced.

When the pillar electrodes 11 can be stably supported by only the silicon nitride film 3, the silicon nitride film 5 may not be provided.

A method of forming a pillar electrode will be described as an example according to this embodiment.

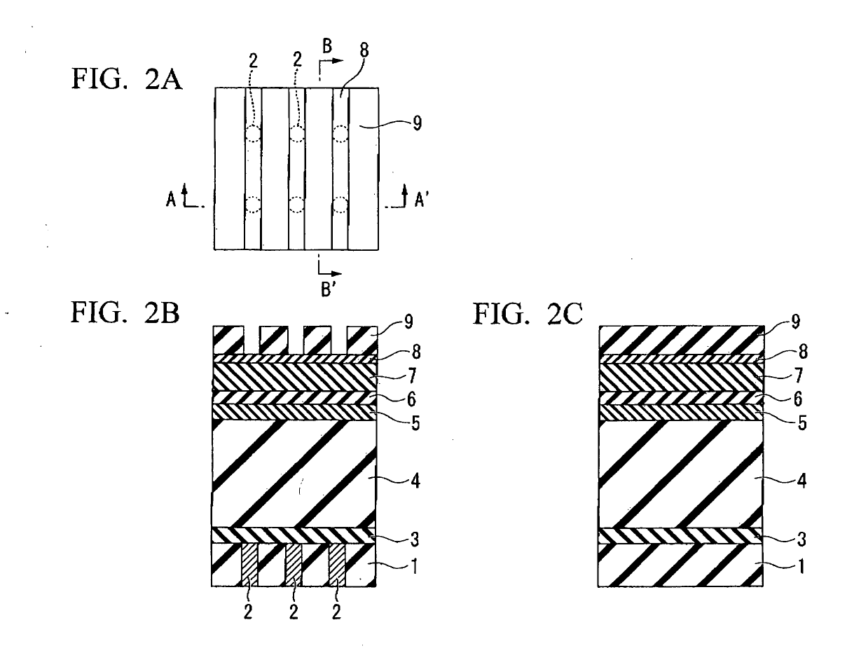

A semiconductor device shown in FIGS. 2A to 2C can be produced as follows.

An inter-layer insulator 1 made of silicon oxide (SiO₂) is formed over a semiconductor substrate (not shown).

An etching mask is formed by a photolithography. A dry etching process is performed using the etching mask to selectively etch the inter-layer insulator 1, thereby forming openings in the inter-layer insulator 1.

A titanium (Ti) film and a titanium nitride (TiN) film are sequentially formed. A tungsten (W) film is deposited on the lamination so as to fill the openings.

The tungsten film over the inter-layer insulator 1 is polished and removed by a CMP (Chemical Mechanical Polishing) method so that the inter-layer insulator 1 is exposed. Thus, the contact plugs 2 made of tungsten or the like are formed in the inter-layer insulator 1. The contact plugs 2 are connected to an active region in the semiconductor substrate.

A first insulating film (silicon nitride film) 3 is deposited over the inter-layer insulator 1 by a CVD method so that the first insulating film (silicon nitride film) 3 has a thickness of about 50 to about 100 nm.

A second insulating film (silicon oxide film) 4 is deposited over the silicon nitride film 3, so that the second insulating film (silicon oxide film) 4 has a thickness of about 1 to about 3 μm. The silicon oxide film 4 may be, but is not limited to, a silicon oxide (BPSG) film containing boron and phosphorus.

A third insulating film (silicon nitride film) 5 is deposited over the silicon oxide film 4, so that the third insulating film (silicon nitride film) 5 has a thickness of about 100 nm.

A fourth insulating film (silicon oxide film) 6 is deposited over the silicon nitride film 5, so that the fourth insulating film (silicon oxide film) 6 has a thickness of about 100 nm.

By controlling the thicknesses of the second insulating film 4 and the fourth, insulating film 6, the aspect ratio of the pillar electrodes 11 can be set at an optimum value. The third insulating film 5 may not be provided around the upper end of the pillar electrode.

A fifth insulating film (carbon film) 7 is deposited over the silicon oxide film 6 by a CVD method, so that the fifth insulating film (carbon film) 7 has a thickness of about 800 nm. As the carbon film 7, an amorphous carbon film may be used. The amorphous carbon film can be formed by a CVD method with a methane (CH₄) gas. The carbon film 7 can be used as a hard mask when first grooves are formed.

A sixth insulating film (ARL (Anti-Reflection Layer) film) 8 is deposited over the carbon film 7. The ARL film 8 can be formed by, but not limited to, depositing a silicon oxide film on a silicon oxynitride (SiON) film to a thickness of about 75 nm. When the ARL film 8 is used, during the photoresist exposure process, the ARL film 8 can prevent reflection, and a photoresist pattern can be formed accurately.

A first photoresist (PR) film 9 is applied onto the ARL film 8, and exposure is performed with a photo-mask for forming first grooves, thereby patterning the first photoresist film 9. Thus, the first photoresist film 9 having a line-and-space pattern is formed, so that the contact plugs 2 are positioned under spaces between the lines of the line-and-space pattern of the first photoresist film 9. The line-and-space pattern has lines and spaces which extend in the direction which is parallel to the B-B′ line and perpendicular to the A-A′ line of FIG. 2A.

Through the above-described process, the semiconductor device shown in FIGS. 2A to 2C can be obtained. FIG. 2A is a fragmentary plan view illustrating a semiconductor device in a step involved in a method of forming the semiconductor device in accordance with the first embodiment of the present invention. FIG. 2B is a fragmentary cross sectional elevation view taken along a A-A′ line of FIG. 2A. FIG. 2C is a fragmentary cross sectional elevation view taken along a B-B′ line of FIG. 2A.

As shown in FIGS. 2A and 2B, the first photoresist film 9 having a line-and-space pattern is formed such that the contact plugs 2 having a generally circular shape in plan view in the inter-layer insulator 1 are positioned under spaces between the lines of the line-and-space pattern of the first photoresist film 9

An anisotropic dry etching process is performed to selectively etch the ARL film 8 by using CF₄ gas with the first photoresist film 9 as a mask.

Another anisotropic dry etching process is performed to selectively etch the carbon film 7 by using oxygen (O₂) gas with the patterned ARL film 8 as a mask.

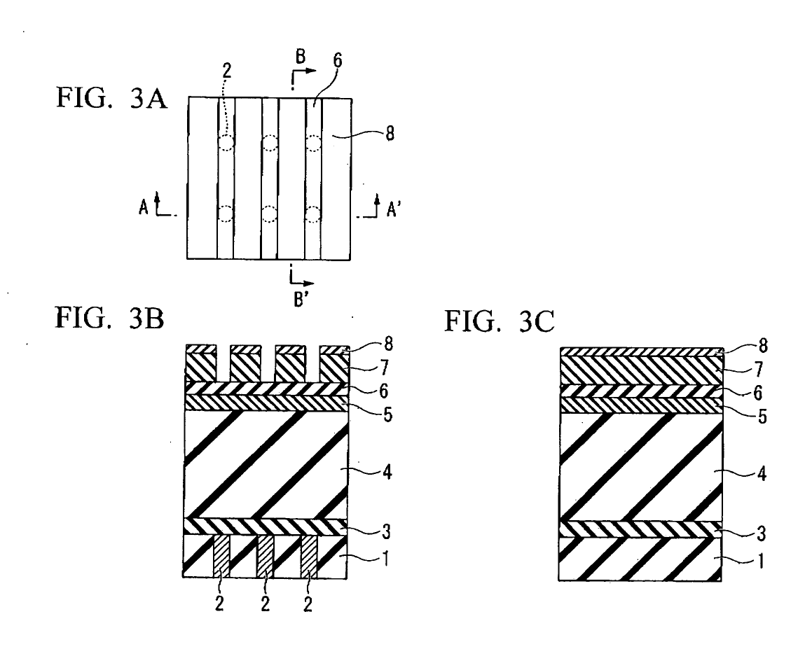

Through the above-described processes, a semiconductor device shown in FIGS. 3A to 3C can be obtained. FIG. 3A is a fragmentary plan view illustrating a semiconductor device in a step subsequent to the step of FIGS. 2A, 2B, and 2C involved in the method of forming the semiconductor device in accordance with the first embodiment of the present invention. FIG. 3B is a fragmentary cross sectional elevation view taken along a A-A′ line of FIG. 3A. FIG. 3C is a fragmentary cross sectional elevation view taken along a B-B′ line of FIG. 3A.

As shown in FIGS. 3A to 3C, the first photoresist film 9 is removed while the anisotropic dry etching process is performed to etch the carbon film 7.

Another anisotropic dry etching process is performed by using the patterned carbon film 7 as a mask (hard mask) to selectively etch the silicon oxide film 6, the silicon nitride film 5, the silicon oxide film 4, and the silicon nitride film 3. During the anisotropic dry etching process, the ARL film 8 over the carbon film 7 is also removed.

The carbon film 7 remaining after the etching process is then removed by an ashing method using oxygen plasma or the like.

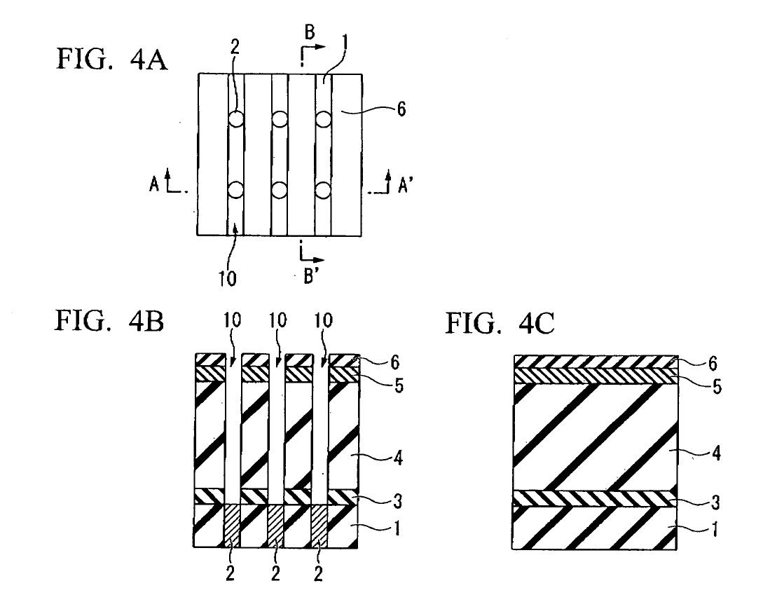

Through the above-described process, a semiconductor device shown in FIGS. 4A to 4C can be obtained. FIG. 4A is a fragmentary plan view illustrating a semiconductor device in a step subsequent to the step of FIGS. 3A, 3B, and 3C involved in the method of forming the semiconductor device in accordance with the first embodiment of the present invention. FIG. 4B is a fragmentary cross sectional elevation view taken along a A-A′ line of FIG. 4A. FIG. 4C is a fragmentary cross sectional elevation view taken along a B-B′ line of FIG. 4A.

As shown in FIGS. 4A and 4B, first grooves 10 are formed which penetrate the silicon oxide film 6, the silicon nitride film 5, the silicon oxide film 4, and the silicon nitride film 3, thereby exposing the contact plugs 2.

In this embodiment, instead of forming a hole pattern in the silicon oxide film 4, a groove pattern (first grooves 10) is formed in the silicon oxide film 4. Etching can be easily performed even though the silicon oxide film 4 has a large thickness as long as the groove pattern (first grooves 10) is formed. A high aspect ratio groove pattern (first grooves 10) can be easily formed. When the silicon oxide film 4 has a large thickness, the formation of a hole pattern with a high aspect ratio can be not easy.

The first grooves 10 are filled by a CVD method, so that an electrode material (Ru film) 11 fills up the first grooves 10 and covers the silicon oxide film 6. Ru is used for the electrode material 11. The electrode material 11 can preferably be etched by using an oxygen-containing gas (oxygen-based gas).

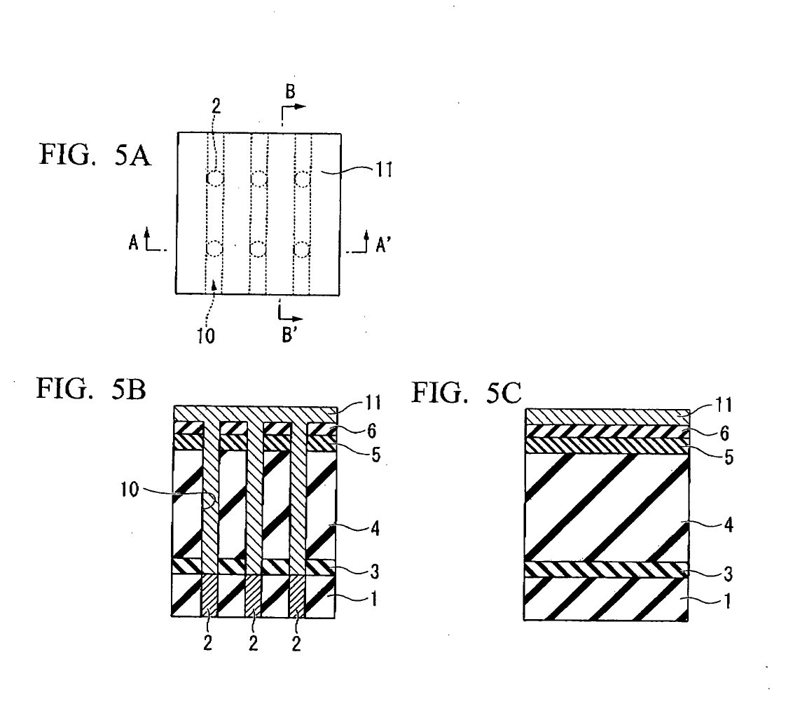

Through the above-described process, a semiconductor device shown in FIGS. 5A to 5C can be obtained. FIG. 5A is a fragmentary plan view illustrating a semiconductor device in a step subsequent to the step of FIGS. 4A, 4B, and 4C involved in the method of forming the semiconductor device in accordance with the first embodiment of the present invention. FIG. 5B is a fragmentary cross sectional elevation view taken along an A-A′ line of FIG. 5A. FIG. 5C is a fragmentary cross sectional elevation view taken along a B-B′ line of FIG. 5A.

A dry etching process is performed to selectively etch the Ru film 11 by using a mixed gas of oxygen (O₂) and chlorine (Cl₂) so that the silicon oxide film 6 is exposed.

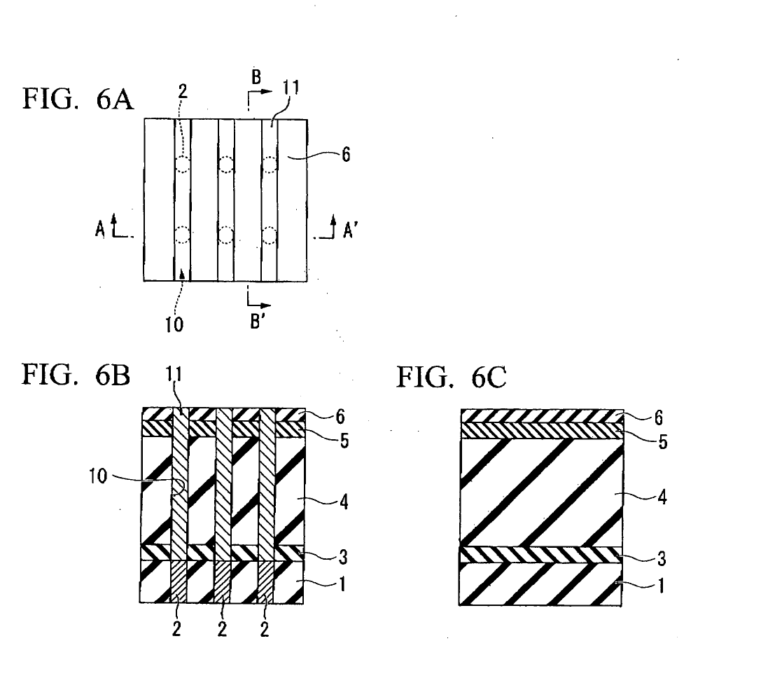

Through the above-described process, a semiconductor device shown in FIGS. 6A to 6C can be obtained. FIG. 6A is a fragmentary plan view illustrating a semiconductor device in a step subsequent to the step of FIGS. 5A, 5B, and 5C involved in the method of forming the semiconductor device in accordance with the first embodiment of the present invention. FIG. 6B is a fragmentary cross sectional elevation view taken along a A-A′ line of FIG. 6A. FIG. 6C is a fragmentary cross sectional elevation view taken along a B-B′ line of FIG. 6A.

As shown in FIGS. 6A, 6B and 6C, the Ru film 11 remains only inside the first grooves 10.

Instead of the dry etching process, a polishing process may be performed to remove the Ru film 11 over the silicon oxide film 6. The polishing process may be, but is not limited to, a CMP method to remove the Ru film 11 over the silicon oxide film 6.

A seventh insulating film (silicon oxide film) 12 is deposited over the silicon oxide film 6 so that the seventh insulating film (silicon oxide film) 12 has a thickness of about 100 nm.

An eighth insulating film (carbon film) 13 is deposited over the silicon oxide film 12, so that the eighth insulating film (carbon film) 13 has a thickness of about 800 nm.

A ninth insulating film (ARL film) 17 is deposited over the carbon film 13 so that the ninth insulating film (ARL film) 17 has a thickness of about 75 nm. The ninth insulating film (ARL film) 17 may have a multi-layer structure of a silicon oxynitride (SiON) film and a silicon oxide film over the silicon oxynitride (SiON) film. The total thickness of the silicon oxynitride (SiON) and the silicon oxide film may be about 75 nm.

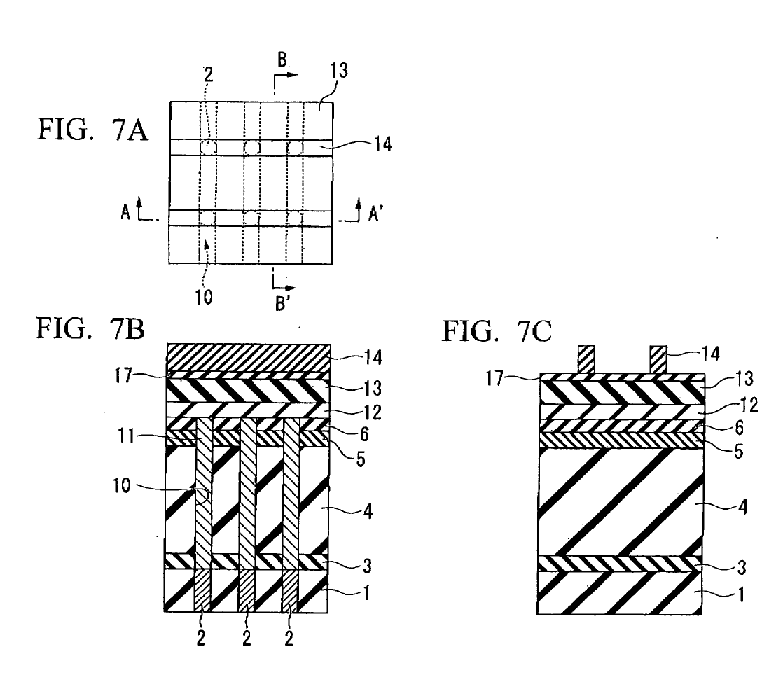

A second photoresist (PR) film 14 having a line-and-space pattern is formed over the ARL film 17. The lines of the line-and-space pattern of the second photoresist (PR) film 14 are positioned over the contact plugs 2. The lines of the line-and-space pattern of the second photoresist (PR) film 14 extend in the direction perpendicular to the direction along which the first grooves 10 extend. The lines of the line-and-space pattern extend in parallel to the A-A′ line of FIG. 7A. The first grooves 10 extend in parallel to the B-B′ line of FIG. 7A.

Through the above-described process, a semiconductor device shown in FIGS. 7A to 7C can be obtained. FIG. 7A is a fragmentary plan view illustrating a semiconductor device in a step subsequent to the step of FIGS. 6A, 6B, and 6C involved in the method of forming the semiconductor device in accordance with the first embodiment of the present invention. FIG. 7B is a fragmentary cross sectional elevation view taken along a A-A′ line of FIG. 7A. FIG. 7C is a fragmentary cross sectional elevation view taken along a B-B′ line of FIG. 7A.

As shown in FIG. 7A, the second photoresist film 14 is formed so that the lines of the line-and-space pattern of the second photoresist film 14 are perpendicular to the Ru films 11 filling in the first grooves 10 in plan view, and that the contact plugs 2 are positioned at crossing points where in plan view the Ru films 11 cross at the right angle the lines of the line-and-space pattern of the second photoresist film 14.

It can be modified that the line-and-space pattern of the second photoresist film 14 cross the Ru films 11 in plan view at an angle different from the right angle. The line-and-space pattern is not limited to be orthogonal to the Ru films 11 in plan view. For example, the line-and-space pattern of the second photoresist film 14 may obliquely cross the Ru films 11 in plan view.

The second photoresist film 14 is formed such that the contact plugs 2 are positioned under the lines of the line-and-space pattern of the second photoresist film 14. As described above, the first grooves 10 are formed such that the contact plugs 2 are positioned under the first grooves 10. Thus, the contact plugs 2 are positioned in plain view at the crossing points where the first grooves 10 cross in plan view the lines of the line-and-space pattern of the second photoresist film 14.

Another anisotropic dry etching process is performed to selectively etch the ARL film 17 by using CF₄ gas with the second photoresist film 14 as a mask.

Another anisotropic dry etching process is performed to selectively etch the carbon film 13 by using oxygen (O₂) gas with the patterned ARL film as a mask.

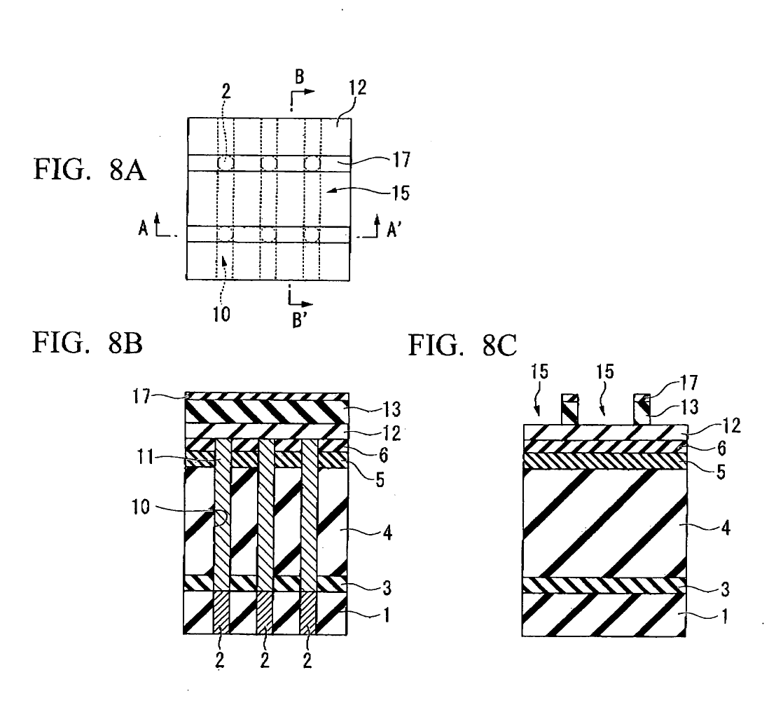

Through the above-described process, a semiconductor device shown in FIGS. 8A to 8C can be obtained. FIG. 8A is a fragmentary plan view illustrating a semiconductor device in a step subsequent to the step of FIGS. 7A, 7B, and 7C involved in the method of forming the semiconductor device in accordance with the first embodiment of the present invention. FIG. 8B is a fragmentary cross sectional elevation view taken along a A-A′ line of FIG. 8A. FIG. 8C is a fragmentary cross sectional elevation view taken along a B-B′ line of FIG. 8A.

As shown in FIG. 8C, the carbon film 13 is patterned, so that second grooves 15 are formed. The second grooves 15 extend in the direction perpendicular to the first grooves 10. When the anisotropic dry etching process is performed to selectively etch the carbon film 13, the photoresist film 14 is removed.

Another anisotropic dry etching process is performed to selectively etch the silicon oxide film 12, the silicon oxide film 6, the silicon nitride film 5, and the silicon oxide film 4. The anisotropic dry etching process is performed by using the carbon film 13 as a mask (hard mask) to form the second grooves 15. The second grooves 15 have a depth such that the silicon nitride film 3 is exposed.

During this etching process for etching the silicon oxide film 4, etching conditions are changed so that the etching rate of the silicon nitride film with respect to the silicon oxide film becomes slower, resulting in that the silicon nitride film 3 remains.

During the anisotropic dry etching process, the ARL film 17 over the carbon film 13 is also etched.

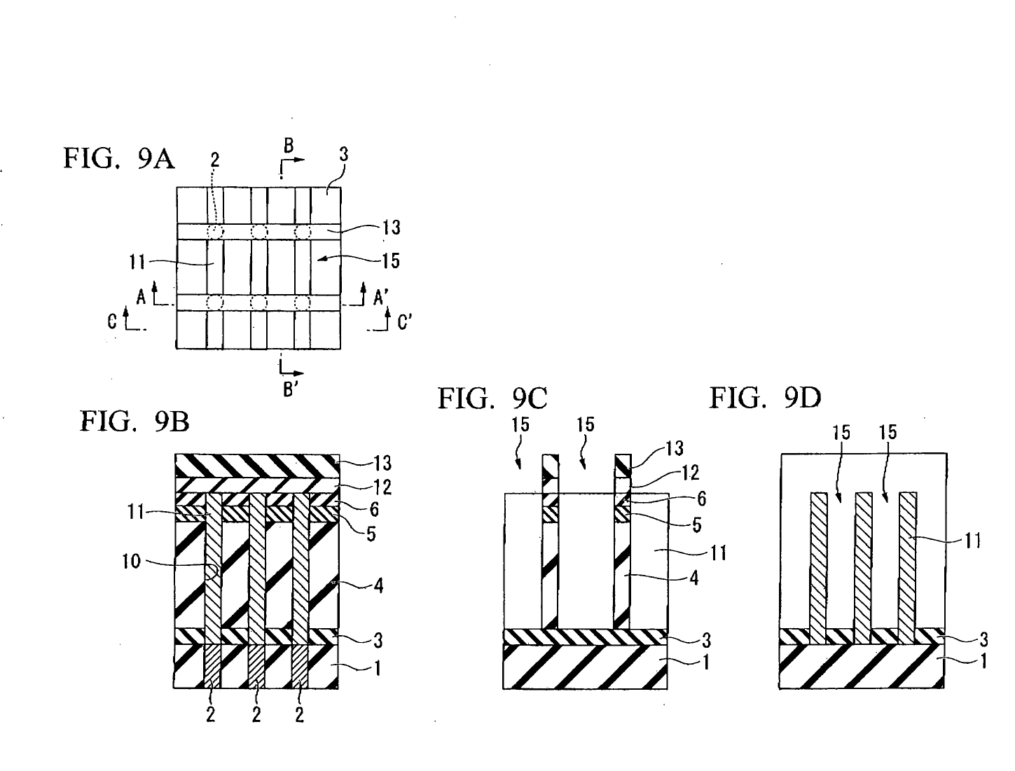

Through the above-described process, a semiconductor device shown in FIGS. 9A to 9D can be obtained. FIG. 9A is a fragmentary plan view illustrating a semiconductor device in a step subsequent to the step of FIGS. 8A, 8B, and 8C involved in the method of forming the semiconductor device in accordance with the first embodiment of the present invention. FIG. 9B is a fragmentary cross sectional elevation view taken along a A-A′ line of FIG. 9A. FIG. 9C is a fragmentary cross sectional elevation view taken along a B-B′ line of FIG. 9A. FIG. 9D is a fragmentary cross sectional elevation view taken along a C-C′ line of FIG. 9A.

As shown in FIG. 9C, under the carbon film 13 there remain the silicon oxide film 12, the silicon oxide film 6, the silicon nitride film 5, and the silicon oxide film 4.

The Ru film 11 can not be etched under the etching conditions used to etch the silicon oxide film and the silicon nitride film. As shown in FIG. 8D, the Ru film 11 remains in the form of walls which corresponds to the pattern of the first grooves 10.

Through a process described below, the silicon oxide film 12 can perform as a mask when the Ru film 11 is etched to form pillar electrodes.

Another anisotropic dry etching process is performed to selectively etch the Ru films 11 by using the silicon oxide film 12 as a mask under the conditions shown on the following Table 1. The anisotropic dry etching process is performed by using an ICP (inductively coupled plasma) type dry etching apparatus. For the anisotropic dry etching process, a mixed gas of oxygen (O₂) and chlorine (Cl₂) is used, so that the carbon film 13 is also removed.

TABLE 1

| Parameters | Conditions | |
|---|---|---|
| O₂ Flow Rate | 1800 sccm to | 1900 sccm |
| Cl₂ Flow Rate | 200 sccm to | 300 sccm |
| Pressure | 10 Pa to | 15 Pa |
| Source Power | 2000 W to | 2200 W |
| Bias Power | 400 W to | 500 W |

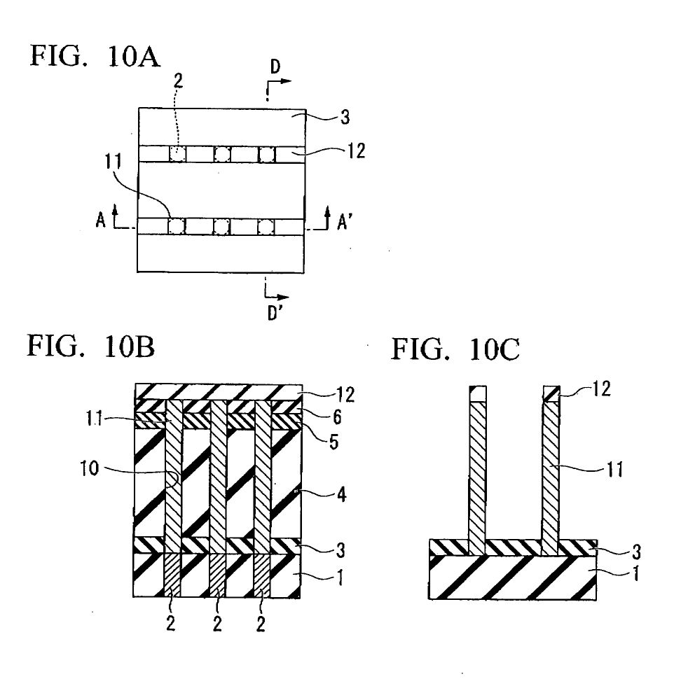

Through the above-described process, a semiconductor device shown in FIGS. 10A to 10C can be obtained. FIG. 10A is a fragmentary plan view illustrating a semiconductor device in a step subsequent to the step of FIGS. 9A, 9B, 9C and 9D involved in the method of forming the semiconductor device in accordance with the first embodiment of the present invention. FIG. 10B is a fragmentary cross sectional elevation view taken along a A-A′ line of FIG. 10A. FIG. 10C is a fragmentary cross sectional elevation view taken along a D-D′ line of FIG. 10A.

As shown in FIGS. 10A, 10B and 10C, the pillar electrodes (Ru film) 11 are formed. The pillar electrodes (Ru film) 11 have bottom portions which are connected to the contact plugs 2 as shown in FIG. 10B. In plan view, the pillar electrodes 11 are positioned in the first grooves 10 and outside the second grooves 15. In plan view, the pillar electrodes 11 overlap the first grooves 10 and do not overlap the second grooves 15. The pillar electrodes (Ru film) 11 are rectangle-shaped in plan view.

Through the above-described process, the strip-shaped third insulating films (silicon nitride film) 5 is formed. The strip-shaped third insulating film (silicon nitride film) 5 connect two adjacent of the pillar electrodes 11 to each other. The strip-shaped third insulating films 5 extend in the same direction (first direction) as the first grooves 10.

The width of the strip-shaped third insulating film 5 raay be the same as the width of the first grooves 10. That is, the width of the strip-shaped third insulating film 5 may be the same as the width of the pillar electrodes 11 in the direction orthogonal to the extension direction of the first grooves 10.

As described above, in this embodiment, the wall-shaped Ru films 11 are formed in the silicon oxide film 4 by using the first grooves 10 and the second grooves 15, and the wall-shaped Ru films 11 are etched by the oxygen-containing gas. Therefore, even though the silicon oxide film 4 has a large thickness, a high aspect ratio pillar electrode can be formed.

A wet etching process is performed to etch the oxide films. The wet etching process is carried out by using a hydrofluoric acid (HF) solution to remove the remaining silicon oxide film 12, silicon oxide film 6, and silicon oxide film 4, and to completely expose the pillar electrodes 11.

In this case, the silicon nitride film 3 over the inter-layer insulator 1 can perform as am etching stopper to an etchant (a hydrofluoric acid solution). It is possible to prevent the hydrofluoric acid solution as an etchant from entering the inter-layer insulator 1 and damaging the inter-layer insulator 1.

Adjacent two of the pillar electrodes 11 are inter-connected to each other through the strip-shaped third insulating film (silicon nitride film) 5. The adjacent two of the pillar electrodes 11 are thus supported by the strip-shaped third insulating film (silicon nitride film) 5. The strip-shaped third insulating film (silicon nitride film) 5 can prevent the pillar electrodes 11 from falling down or collapsing during the wet etching process.

Through the above-described process, the semiconductor device 101 shown in FIGS. 1A to 1C can be obtained.

This embodiment can preferably be applied to cases where the dry etching process need to be performed using the oxygen-containing gas, and a photoresist film or a carbon film can not be used as a mask material.

The above-described method of forming the semiconductor device is performed as follows. A first groove pattern which has the first grooves 10 is formed in the insulating film. The first grooves 10 are filled with the pillar electrode material films A second groove pattern which has the second grooves 15 is formed over the first grooves 10 which are filled with the pillar electrode material films. The second grooves 15 cross the first grooves 10 in plan view. The second grooves 15 are used to selectively etch the pillar electrode material films to form pillar electrodes. In plan view, the pillar electrodes 11 are positioned in the first grooves 10 and outside the second grooves 15. In plan view, the pillar electrodes 11 overlap the first grooves 10 and do not overlap the second grooves 15. The pillar electrodes (Ru film) 11 are rectangle-shaped in plan view. The above-described method uses two groove patterns to form the pillar electrodes (Ru film) 11. Therefore, even though the pillar electrodes 11 need to have a high aspect ratio, the pillar electrodes 11 can be easily formed. Further, even though the pillar electrodes 11 are made of a conductive material, such as Ru which can be etched by the oxygen-containing gas, the semiconductor device 101 having the pillar electrodes 11 with the high aspect ratio can be easily formed.

### Second Embodiment

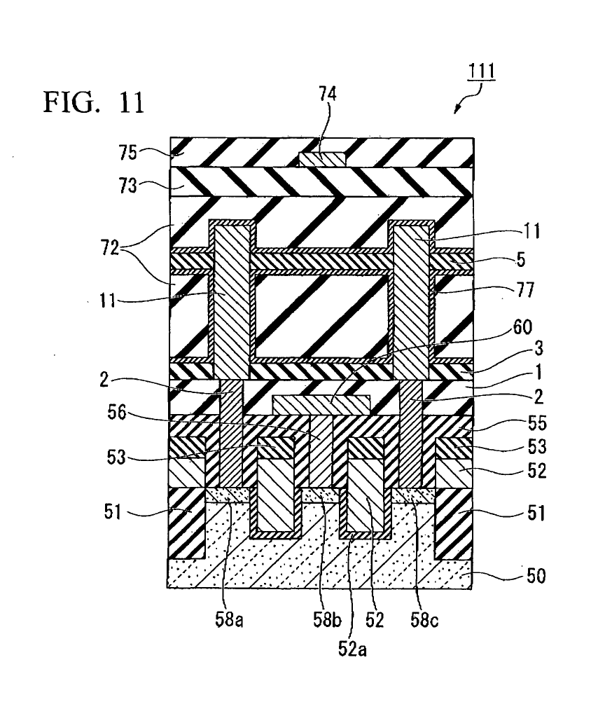

FIG. 11 is a fragmentary cross sectional view illustrating a DRAM memory cell having pillar electrodes in accordance with the second embodiment of the present invention.

As shown in FIG. 11, a semiconductor device 111 has a substrate (semiconductor substrate) 50, an inter-layer insulator 55 formed on the substrate 50, an inter-layer insulator 1 formed on the inter-layer insulator 55, a first insulating film (silicon nitride film) 3 formed on the inter-layer insulator 1, an upper electrode 72 formed on the silicon nitride film 3, an inter-layer insulator 73 formed on the upper electrode 72, and a surface protective film 75 formed on the inter-layer insulator 73.

Element isolation areas 51 formed by filling an insulator in grooves are formed in the substrate 50, and impurity diffusion layer areas 58a to 58c are formed in an active area of the semiconductor substrate 50 defined by the element isolation areas 51. The impurity diffusion layer areas 58a to 58c function as source and drain areas of a MOS type transistor.

Groove-shaped gate electrodes 52 axe formed to be opposite the substrate 50 through a gate insulating film 52a made of silicon oxide or the like and to protrude from the substrate 50. The gate electrode 52 is also formed on the element isolation area 51. An insulating film 53 made of silicon nitride or the like is formed on the gate electrodes 52.

For a MOS type transistor, a gate electrode having a shape other than a groove shape may be used. For example, a planar or vertical transistor may be used.

The gate electrode 52 on the element isolation area 51 functions as a word line of the DRAM.

The insulating film 53 protects the top surfaces of the gate electrodes 52.

A contact plug 56 is buried in the inter-layer insulator 55 so as to connect the impurity diffusion layer area 58b and a bit interconnect 60.

The inter-layer insulator 1 is formed on the inter-layer insulator 55, and contact plugs 2 are buried in the insulating layer 1 so as to pass through the inter-layer insulator 1 and the inter-layer insulator 55 and to be connected to the impurity diffusion layer areas 58a and 58c.

Pillar electrodes (Ru film) 11 are formed in the upper electrode 72 so as to be connected to the contact plugs 2. The pillar electrodes 11 are connected to the impurity diffusion layer areas 58a and 58c through the contact plugs 2. For this reason, the pillar electrodes 11 function as lower electrodes with respect to the upper electrode 72.

A capacitor insulating film 77 is formed in the upper electrode 72 so as to cover the exposed surfaces of the pillar electrodes (Ru film) 11, the silicon nitride film 3, and the silicon nitride film 5. The capacitor insulating film 77 may be made of, for example, hafnium oxide (HfO₂), aluminum oxide (Al₂O₃), strontium titanate (SrTiO₃), zirconium oxide (ZrO₂), or a laminated film of these materials. Capacitors connected to the contact plugs 2 are formed by the pillar electrodes (lower electrodes) 11, the capacitor insulating film 77, and the upper electrode 72.

The upper electrode 72 may be made of a metal, such as Ru, W, or the like, or polysilicon. When the upper electrode 72 is made of a metal other than Ru or polysilicon, a thin metal layer made of TN may be formed on the capacitor insulating film 77 to a thickness of 15 to 20 nm.

The pillar electrodes 71 are formed such that the base ends thereof are supported by the first insulating film 3 and the upper parts thereof are supported by the third insulating film (silicon nitride film) 5.

An interconnect 74 is buried in the surface protective film 75. Though not shown, the interconnect 74 is connected to the upper electrode 72 to supply a predetermined potential (plate potential) to the upper electrode 72. Thus, the semiconductor device 111 according to this embodiment can be used, for example, as memory cells of the DRAM having a good electric charge retaining characteristic (refresh characteristic).

A method of manufacturing the semiconductor device 111 according to this embodiment will be described.

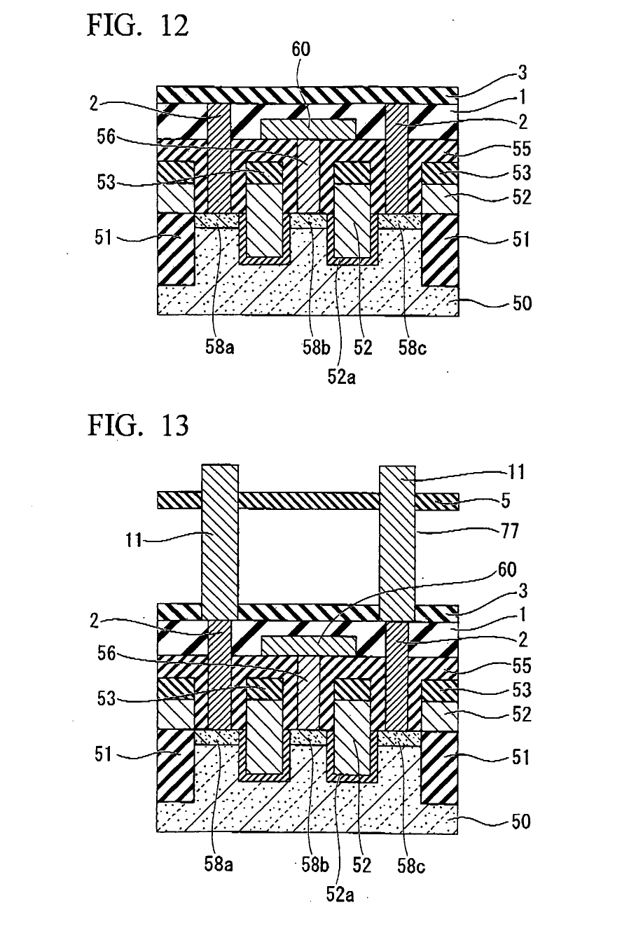

FIG. 12 is a fragmentary cross sectional elevation view illustrating a semiconductor device in a step involved in a method of forming the semiconductor device of FIG. 11 in accordance with the second embodiment of the present invention.

A semiconductor device shown in FIG. 12 is produced as follows.

First, the substrate (semiconductor substrate) 50 made of P-type silicon is prepared.

Grooves are formed in the substrate (semiconductor substrate) 50, and an insulating film is filled in the grooves so as to form the element isolation areas 51. Thus, the active area defined by the element isolation areas 51 is formed.

An N-type impurity, such as phosphorus or the like, is ion-implanted into the surface of the substrate 50 corresponding to the active region so as to form the impurity diffusion layer areas 58a to 58c.

The groove-shaped gate electrodes 52 are formed at the surface of the substrate 50 corresponding to the active area so as to be opposite the semiconductor substrate 50 through the gate insulating film 52a made of silicon oxide or the like. Simultaneously, the gate electrode 52 is also formed on the element isolation area 51 so as to connect the groove-shaped gate electrodes between adjacent memory cells.

Prior to patterning of the gate electrodes 52, the insulating film 53 made of silicon nitride or the like is deposited on a material for a gate electrode and patterned at the same time with the gate electrodes.

The inter-layer insulator 55 is formed so as to cover the gate electrodes 52, the insulating film 53, and the surface of the substrate 50.

The contact plug 56 is formed in the inter-layer insulator 55 so as to be connected to the impurity diffusion layer area 58b, and then the bit interconnect 60 is formed so as to be connected to the contact plug 56.

The inter-layer insulator 1 is formed so as to cover the inter-layer insulator 55, and then the contact plugs 2 are formed so as to pass through the inter-layer insulator 1 and the inter-layer insulator 55 and to be connected to the impurity diffusion layer areas 58a and 58c.

The first insulating film (silicon nitride) 3 is formed on the inter-layer insulator 1.

Through the above-described process, the semiconductor device shown in FIG. 12 is obtained.

FIG. 13 is a fragmentary cross sectional elevation view illustrating a semiconductor device in a step subsequent to the step of FIG. 12 involved in the method of forming the semiconductor device of FIG. 11 in accordance with the second embodiment of the present invention.

A semiconductor device shown in FIG. 13 is produced by using the method of manufacturing a semiconductor device described in the first embodiment.

The inter-layer insulator 1, the contact plugs 2, and the first insulating film (silicon nitride film) 3 shown in FIG. 12 are the same as the inter-layer insulator 1, the contact plugs 2, the first insulating film (silicon nitride film) 3 shown in the first embodiment Together with these members, the pillar electrodes (Ru film) 11 are formed on the silicon nitride film 3 so as to be connected to the contact plugs 2 by using the method of manufacturing a semiconductor device according to the first embodiment.

The inter-layer insulator 1 is covered with the silicon nitride film 3, so there is no case where a MOS type transistor provided in the substrate below the inter-layer insulator 1 is damaged by wet etching for exposing the pillar electrodes 11 during the manufacturing process.

As shown in FIG. 13, the pillar electrodes (Ru film) 11 are connected to the contact plugs 2. Thus, the pillar electrodes 11 function as a lower electrode of a capacitor.

The silicon nitride film 3 is formed at the base ends of the pillar electrodes 11. Thus, the silicon nitride film 3 prevents the pillar electrodes 11 from being collapsed.

The third insulating film (silicon nitride film) 5 is formed so as to connect the upper parts of the pillar electrodes 11. Thus, the silicon nitride film 5 prevents the pillar electrodes 11 from being collapsed.

The semiconductor device shown in FIG. 11 is produced as follows.

First, the capacitor insulating film 77 is formed so as to cover the exposed surfaces of the pillar electrodes (Ru film) 11, the silicon nitride film 3, and the silicon nitride film 5

The upper electrode 72 is formed of a metal, such as Ru, W, or the like, or polysilicon by using a CVD method.

The inter-layer insulator 73, the interconnect 74, and the surface protective film 75 are formed on the upper electrode 72.

Through the above-described process, the semiconductor device 111 shown in FIG. 11 can be obtained.

The patterns of the first grooves 10 and the second grooves 15 described in the first embodiment may be set so as to cross each other at an optimum angle conforming to the layout of the contact plugs 2 constituting the memory cells.

According to the method of manufacturing the semiconductor device 111 according to this embodiment, a high aspect ratio metal pillar may be used as a lower electrode of a capacitor. The lower electrode may be made of a material for which etching should be performed with oxygen-based gas. In particular, when Ru is used as the electrode material of the capacitor, a capacitor element can be formed with an improved leakage breakdown voltage of the capacitor insulating film 77. Therefore, a capacitor element having large electrostatic capacitance and excellent electrical characteristics can be easily formed, and as a result, the semiconductor device 11 can be used as a DRAM element having a good electric charge retaining characteristic (refresh characteristic).

The method of manufacturing a pillar electrode described in the first embodiment may be applied to a case where a pillar (columnar) electrode is formed, other than the DRAM element.

The invention relates to a semiconductor device having a pillar electrode and a method of manufacturing a semiconductor device, and is applicable to the industries where semiconductor devices are manufactured and used.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming first grooves in a first insulating layer;
forming a conductive material that fill in each of the first grooves;
forming a first mask over the first insulating layer and the conductive material, the first mask having openings that define second grooves crossing the first grooves in plan view; and
forming the second grooves in the first insulating layer and the conductive material by using the first mask,
wherein a plurality of conductive pillars are formed by removing a part of the conductive material in each of the first grooves.

2. The method according to claim 1, wherein forming the second grooves comprises:
selectively removing the first insulating layer and having the conductive material remain in the first grooves; and
removing the part of the conductive material which remains in the first grooves.

3. The method according to claim 2, wherein removing the part of the conductive material comprises an anisotropic etching process using an oxygen-containing gas.

4. The method according to claim 3, wherein the first mask comprises a stack of first and second layers in this order, the first layer is not etched by the oxygen-containing gas and the second layer is etched by the oxygen-containing gas.

5. The method according to claim 1, wherein the conductive material includes Ru, and the first mask includes a carbon layer.

6. The method according to claim 1, further comprising:
forming an interlayer insulator under the first insulating layer; and
forming contact plugs in the interlayer insulator before forming the first insulating layer,
wherein the first grooves expose upper surfaces of the contact plugs, and
the conductive material connects directly to the contact plugs.

7. The method according to claim 6, wherein forming the first grooves in the first insulating layer comprises:
forming a second mask over the first insulating layer, the second mask having a line-and-space pattern, spaces of the line-and-space pattern of the second mask extending over the contact plugs in plan view; and
selectively etching the first insulating layer by using the second mask to form the first grooves in the first insulating layer.

8. The method according to claim 7, wherein forming the second mask over the first insulating layer comprises:
forming a second insulating layer over the first insulating layer;
forming a first resist pattern on the second insulating layer, the first resist pattern having a first line-and-space pattern, spaces of the first line-and-space pattern extending over the contact plugs in plan view, the spaces and lines of the first line-and-space pattern extending in parallel to an extension direction along which the first grooves extend; and
selectively etching the second insulating layer by using the first resist pattern to define the second insulating layer into the second mask.

9. The method according to claim 8, wherein forming the first mask comprises:
forming a third insulating layer over the conductive material and the first insulating layer;
forming a second resist pattern on the third insulating layer, the second resist pattern having a second line-and-space pattern, lines of the second line-and-space pattern extending over the contact plugs in plan view, spaces of the second line-and-space pattern crossing the conductive material that fills in the first grooves; and
selectively etching the third insulating layer to define the second insulating layer into the first mask.

10. The method according to claim 9, wherein the first mask includes a first anti-reflection film comprising silicon oxynitride, and the second mask includes a second anti-reflection film comprising silicon oxynitride, and the first anti-reflection film performs as an anti-reflector when a first exposure process is carried out to form the first resist pattern, and the second anti-reflection film performs as an anti-reflector when a second exposure process is carried out to form the second resist pattern.

11. The method according to claim 9, wherein the second lines and spaces of the line-and-space pattern extend in a direction perpendicular to an extending direction along which the first grooves extend.

12. The method according to claim 1, further comprising:
removing the first insulating layer under the first mask after forming the second grooves.

13. The method according to claim 12, further comprising:
forming a fourth insulating layer in the first insulating layer,
wherein the fourth insulating layer connects the conductive pillars to each other, and the fourth insulating layer supports the conductive pillars during removing the first insulating layer.

14. The method according to claim 12, further comprising:
forming a dielectric film on the conductive pillars; and
forming a top electrode on the dielectric film, to operate as capacitors.

15. A method of forming a semiconductor device, the method comprising:
forming a first insulating layer,
forming first openings in the first insulating layer to penetrate the first insulating layer, each of the openings extending in a first direction in plan view;
filling a conductive film into the first openings;
forming a first mask on the first insulating layer and the conductive film, the first mask having second openings, each of the second openings extending in a second direction which crosses to the first direction in plan view; and
performing a dry etching to remove a part of the conductive film which is exposed from the first mask for forming a plurality of conductive pillars made of the conductive film,
wherein the dry etching is performed by using at least a first gas and a second gas, the second gas being different from the first gas.

16. The method according to claim 15, wherein the first mask comprises a first mask layer and a second mask layer on the first mask layer, the first mask layer is not etched by the first gas.

17. The method according to claim 16, wherein the first gas is oxygen.

18. The method according to claim 15, further comprising:
removing the conductive film on the first insulating layer and having the conductive film remain in the first openings before forming the first mask.

19. A semiconductor device comprising:
an insulating layer;
contact plugs in the insulating layer;
pillar electrodes extending upwardly from the contact plugs; and
an insulating supporter which connects the pillar electrodes to each other, the insulating supporter supporting the pillar electrodes, and the insulating supporter having a width which is substantially identical with a first dimension of the pillar electrodes, the first dimension being defined in a horizontal direction perpendicular to an extending direction of the insulating supporter.

20. The semiconductor device according to claim 19, further comprising:
transistors eclectically connected to the pillar electrodes;
a dielectric insulating film covering the pillar electrodes; and
a top electrode disposed facing to each of the pillar electrodes with an intervention of a dielectric insulating film therebetween.
